(19) United States
(12) Patent Application Publication
(10) Pub. No.: US 2026/0101554 A1
(43) Pub. Date: Apr. 9, 2026

(54) SMALL PERIOD SUPERJUNCTION DEVICE

(71) Applicant: The Government of the United States of America, as represented by the Secretary of the Navy, Arlington, VA (US)

(72) Inventors: Alan G. Jacobs, Rockville, MD (US); Karl D. Hobart, Alexandria, VA (US); Michael A. Mastro, Fairfax, VA (US); Emma G. Rocco, Mount Rainier, MD (US); Cory D. Cress, Springfield, VA (US)

(73) Assignee: The Government of the United States of America, as represented by the Secretary of the Navy, Arlington, VA (US)

(21) Appl. No.: 19/350,149

(22) Filed: Oct. 6, 2025

Related U.S. Application Data
(60) Provisional application No. 63/704,236, filed on Oct. 7, 2024.

(51) Int. Cl. H10D 62/815; H10D 62/00; H10D 62/824

(52) U.S. Cl. CPC H10D 62/8161; H10D 62/052; H10D 62/824

(57) ABSTRACT

A superjunction superlattice semiconductor device and a method of making the same are presented. In embodiments, the method includes: growing, on a substrate, alternating n-type and p-type semiconductor layers in the plane of the substrate, thereby forming a superjunction region providing a depletion effect; etching opposing sides of the superjunction region and the substrate to form spaced first and second sloped sidewalls, wherein each of the first and second sloped sidewalls extend at an oblique angle with respect to a top surface of the substrate; forming a first metal contact in communication with the first sidewall; and forming a second metal contact in communication with the second sidewall.

### CROSS-REFERENCE TO RELATED APPLICATIONS

This application is a Nonprovisional of, and claims the benefit of priority under 35 U.S.C. § 119 based on, U.S. Provisional Patent Application No. 63/704,236 filed Oct. 7, 2024. The Provisional application and all references cited herein are hereby incorporated by reference into the present disclosure in their entirety.

### FEDERALLY SPONSORED RESEARCH AND DEVELOPMENT

The United States Government has ownership rights in this invention. Licensing inquiries may be directed to Office of Technology Transfer, US Naval Research Laboratory, Code 1004, Washington, D.C. 20375, USA; +1.202.767.7230; nrltechtran@us.navy.mil, referencing Navy Case No. 212354-US02.

### BACKGROUND OF THE INVENTION

Aspects of the present invention relate generally to semiconductor devices and manufacturing and, more particularly, to superjunction devices and methods of making the same.

Power electronic devices for control of high voltages and high currents exhibit an inherent tradeoff between the voltage that is able to be controlled and the area specific device resistance. This tradeoff is inherent to the device structure and material and stems from the need to use additional material thickness to hold off higher voltages, thereby adding additional resistance and resultant power losses and inefficiencies. One method of addressing this challenge is to utilize the superjunction device topology (i.e., alternating regions of p-type and n-type material layers) to create devices able to control higher voltages while reducing the device resistance over standard device geometries.

In general, a superjunction device or superjunction Metal-Oxide-Semiconductor Field-Effect Transistor (MOSFET) refers to a type of MOSFET that utilizes a superjunction structure of alternating p-type and n-type layers or “pillars” of semiconductor material in place of a conventional n-type material in the drift region. This superjunction structure enables a higher doping concentration in the drift region of a vertical rectifier or transistor while maintaining a high breakdown voltage.

A superjunction structure results in a two-dimensional (2D) depletion effect, yielding a more uniform electric field profile and thus a higher breakdown voltage (BV) compared to the triangular electric field profile of a one-dimensional (1D) depletion effect. It is crucial for the dosage of the p-type and n-type pillars to be equal in a superjunction structure, and the carrier density of the p-type and n-type pillars are an important design parameter.

The properties of devices that use superjunction structure/regions are sensitive to both the superjunction period, doping concentration of the p-type and n-type pillars, and balance between the charge within the p-type and n-type pillars. For improved device resistance, generally, a higher doping is desired. To maintain the superjunction effect, the alternating n-type and p-type pillars must fully deplete. For higher doped pillars, a smaller superjunction periodicity is required to enable full depletion and utilization of the superjunction effect. Additionally, charge balance between n-type and p-type regions must be maintained close to neutral to fully utilize the improved superjunction performance.

Superjunction devices have been commercialized with silicon devices (and are in development for silicon carbide (SiC) devices), and there exists significant interest in applying superjunction device geometries to additional materials. To create superjunction devices, two existing methods are utilized: (1) cyclic (iterative) layer growth and aligned implant, and (2) deep trench etch and regrowth/filling of the trenches. In both of these methods, the pitch between n-type and p-type layers is limited by the processes used to form the alternating p-type and n-type regions, and is generally limited to micron-scale dimensions. The term pitch as used herein refers to a distance between a center of one of the pillars (n-pillar or p-pillar) of a superjunction device and the center of an adjacent pillar of the same type. In general, a small periodicity of alternating n- and p-type pillars is desired. The term period as used herein refers to the thickness/dimension of an n-type and a p-type region of a superjunction structure, together.

### SUMMARY OF THE INVENTION

In a first aspect of the invention, there is a method of making a superjunction semiconductor device including: growing, on a substrate, alternating n-type and p-type semiconductor layers in the plane of the substrate, thereby forming a superjunction region providing a depletion effect; etching opposing sides of the superjunction region and the substrate to form spaced first and second sloped sidewalls, wherein each of the first and second sloped sidewalls extend at an oblique angle with respect to a top surface of the substrate; forming a first metal contact in communication with the first sidewall; and forming a second metal contact in communication with the second sidewall. In implementations, the superjunction region is comprised of material selected from the group consisting of: aluminum nitrides, gallium nitrides, scandium nitrides, and alloys thereof.

The method may further include forming an epitaxial cap layer of semiconductor material over a top surface of the superjunction region between the first and second sloped sidewalls. In embodiments, each of the n-type layers and p-type layers have a graded composition. The method may utilize polarization doping to generate the superjunction region. In implementations, the method further includes depositing a first material layer on the first sloped sidewall such that the first material layer extends across the alternating n-type and p-type semiconductor layers, wherein the first metal contact is formed on the first material layer. In embodiments, the first material layer is doped via ion implantation. The first material layer may be an n-type or p-type semiconductor. The n-type semiconductor may be aluminum nitrides, gallium nitrides, scandium nitrides, and alloys thereof. In embodiments, the method includes depositing a second material layer onto the second sloped sidewall such that the second material layer extends across the alternating n-type and p-type semiconductor layers, wherein the second metal contact is formed on the second material layer. In implementations, the second material layer is a p-type semiconductor material. The second material layer may be selected from the group consisting of: aluminum nitrides, gallium nitrides, scandium nitrides, and alloys thereof.

In another aspect of the invention, there is a superjunction superlattice semiconductor device including: a substrate with a superlattice body grown thereon, wherein the superlattice body includes alternating n-type and p-type semiconductor layers grown in plane with the substrate to form a superjunction region providing a depletion effect, wherein the superlattice body includes first and second sloped sidewalls extending at an oblique angle to a top surface of the substrate; a semiconductor cap layer extending over on a top surface of the superlattice body; a first metal contact in communication with the first sidewall and the semiconductor cap layer; and a second metal contact in communication with the second sidewall and the semiconductor cap layer. In embodiments, a first material layer is located between the first sloped sidewall and the first metal contact. In implementations, the device includes a supporting substrate, wherein the first material layer is deposited on a portion of the supporting substrate. In embodiments, the device includes a second material layer between the second sloped sidewall and the second metal contact. The second material layer may be deposited on a portion of a supporting substrate.

In embodiments of the invention, the superjunction region is comprised of material selected from the group consisting of: aluminum nitrides, gallium nitrides, scandium nitrides, and alloys thereof. The device may include third and fourth metal contacts in communication with the first sloped sidewall. In implementations, the device further includes a supporting substrate; a first material layer located between the first metal and fourth metal contacts and the superlattice body, and between the first and fourth metal contacts and the supporting substrate; an oxide layer formed over a surface portion of the first material layer between the third metal contact and the first material layer; and a second material layer located between the second metal contact and the superlattice body, and between the second metal contact and the supporting substrate.

### BRIEF DESCRIPTION OF THE DRAWINGS

Aspects of the present invention are described in the detailed description which follows, in reference to the noted plurality of drawings by way of non-limiting examples of exemplary embodiments of the present invention.

FIG. 1 is a partial cross-sectional side view of a superlattice structure having graded layers, and an associated carrier density periodicity in accordance with embodiments of the invention.

FIG. 2 is a cross-sectional side view of a superjunction (SJ) Schottky diode, in accordance with embodiments of the invention.

FIG. 3 is a is a cross-sectional side view of another SJ Schottky diode, in accordance with embodiments of the invention.

FIG. 4 is a is a cross-sectional side view of a SJ P-N diode in accordance with embodiments of the invention.

FIG. 5A is a perspective side view of a stage 500A of a superlattice structure device in accordance with embodiments of the invention.

FIG. 5B is a perspective side view of a stage 500B of a superlattice structure device in accordance with embodiments of the invention.

FIG. 5C is a perspective side view of a stage 500C of a superlattice structure device in accordance with embodiments of the invention.

FIG. 5D is a perspective side view of a stage 500D of a superlattice structure device in accordance with embodiments of the invention.

FIG. 5E is a perspective side view of a stage 500E of a superlattice structure device in accordance with embodiments of the invention.

FIG. 6 shows a flowchart of an exemplary method in accordance with aspects of the present invention.

### DETAILED DESCRIPTION

Aspects of the present invention relate generally to semiconductor devices and manufacturing and, more particularly, to superjunction devices and methods of making the same. In embodiments, monolithic growth of semiconductors on a substrate is utilized to form a superlattice of n-type and p-type pillars or regions in the same plane as a substrate, thereby forming a superjunction region of a superjunction device. Many superjunction devices can be fabricated from this basic building block by etching sloped trenches through the superlattice of n-type and p-type regions, and contacting the superlattice via its sloped sidewalls, or indirectly through material layers deposited on the sloped sidewalls.

In accordance with embodiments of the invention, the superlattice may be formed by extrinsically doping the layers during growth (impurity doping), by polarization doping, or by a combination of extrinsic and polarization doping. The doped layers of the superlattice may be made from any suitable semiconductor material where the growth of the material enables facile control of thin superlattice periodicities for improved superjunction device properties.

In general, impurity doping is the process of intentionally adding impurities or dopants to a semiconductor to alter its electrical properties. In contrast, polarization-induced doping is a phenomenon that occurs during growth of graded materials made of polar semiconductors, where the dipole changes along a growth axis result in a net bulk charge density. Polarization doping leverages the inherent polarization properties of the semiconductor material's crystal structure to create a separation of charge, effectively mimicking the effects of doping without the need to add chemical impurities.

Polarization doping occurs in some semiconductor systems due to the atomic structure and properties of the semiconductor material when used in a structure with composition gradients. Exemplary semiconductor systems include aluminum nitride (AlN), gallium nitride (GaN), and alloys thereof, where a sharp change in composition may create a two-dimensional (2D) electron or hole gas. Embodiments of the invention utilize AlN and aluminum gallium nitride (AlGaN) materials to form polarization-doped superjunction structures. For continually graded compositions, a three-dimensional (3D) (volumetric) electron or hole gas may be created.

Polarization doping is inherently tied to the material structure and composition, meaning that the charge density from polarization doping is directly related to the composition structure of the semiconductor. As such, a superlattice that grades from AlN to GaN and back to AlN will inherently have a balanced charge profile from polarization creating a p-type and n-type regions, respectively, in the case of growth in a metal-polar direction. Subsequent iterations of the repeat unit (AlN graded to GaN graded to AlN) add an additional set of p-type and n-type regions. Thick material made up of many superlattice periods (e.g., >100) can then be formed for increased current handling capabilities and/or a reduced device footprint, in accordance with embodiments of the invention.

Although such polarization doped structures are intrinsically charge-balanced (since carriers are generated due to the atomic structure), they may show a net offset from balance due to unintentional impurity inclusion (e.g., oxygen or carbon inclusion during growth). As such, a small intentional dopant may simultaneously be included to either offset that unintentional doping, or to intentionally produce periods of the superlattice superjunction with a net doping for field control, robust avalanche behavior, or other purposes. Other materials, such as scandium nitride (ScN) or yttrium nitride (YN), may equally be used in such polarization doped structures. In such structures, the choice of material, composition gradient, and layer thickness determines the polarization induced carrier density. For instance, it may be beneficial to grade from AlN to Al_{0.9}Ga_{0.1}N within a period, instead of AlN to GaN, to tune the carrier density to the desired value or to reduce the strain induced from lattice mis-match.

Implementations of the invention provide improvements over silicon carbide (SIC) based superjunction structures by utilizing wider bandgap materials with higher critical electric fields, resulting in reduced device losses and increased efficiency. Ultra-wide bandgap materials such as aluminum gallium nitride (AlGaN or AlₓGa₍₁₋ₓ₎N) have much higher critical electric fields than SiC. In the case of AlₓGa₍₁₋ₓ₎N, the composition determines the critical electric field with more aluminum rich alloys (x towards unity) having the highest critical electric field.

Advantageously, embodiments of the invention grow the alternating n-type and p-type pillars of a superjunction structure, which results in a much smaller periodicity (i.e., on the scale of tens of nanometers (nm)) compared to the periodicity of superjunction structures manufactured via lithography (i.e., on the scale of microns).

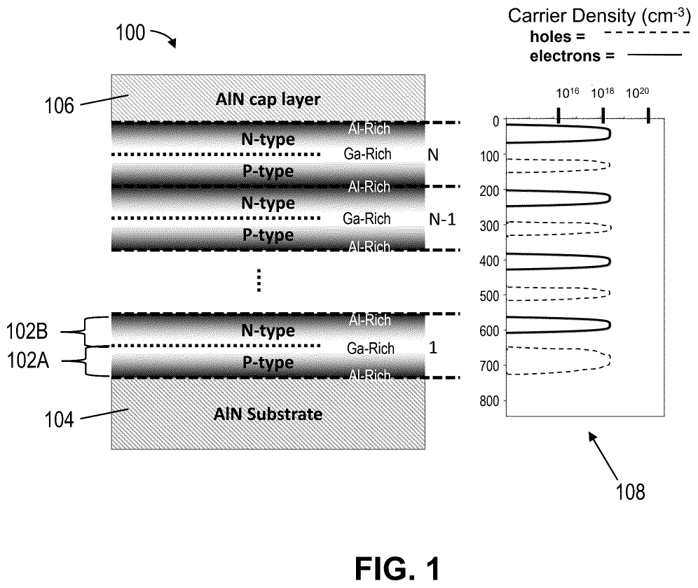

FIG. 1 is a partial cross-sectional side view of a superlattice structure 100 having graded layers, and an associated carrier density periodicity in accordance with embodiments of the invention. In the example of FIG. 1, the superlattice structure 100 includes alternating p-type and n-type semiconductor portions (e.g., 102A and 102B), comprised of graded layers of aluminum gallium nitride (AlGaN or AlₓGa₍₁₋ₓ₎N) materials grown on a metal polar substrate 104, with a cap layer 106 extending over the graded layers. In implementations, the graded layers comprise an AlGaN material (AlGaN or AlₓGa₍₁₋ₓ₎N) grown on a metal polar substrate of AlN with an AlN cap layer.

The periodicity of the layers is illustrated by a graph 108, wherein the superlattice structure 100 has a total periodicity of 180 nm. More specifically, the graph 108 includes a vertical axis representing the thickness distance in nm, which depicts 4 periods of a superlattice structure that are ˜720 nm in total thickness (180 nm period). The horizontal axis is the carrier density in log units showing each period having ˜10¹⁸ carriers for a particular simulation, which is a 30% grade (AlN to Al_{0.7}Ga_{0.3}N). As noted above, the term period as used herein refers to the thickness/dimension of both an n-type region (e.g., 102A) and an adjacent p-type region (e.g., 102B), together. See, for example, period 1 comprised of regions 102A and 102B (demarcated between dashed lines) in FIG. 1. In implementations, the growth of alternating layers 102A and 102B results in an aluminum-rich (Al-rich) region that grades to a more gallium-rich (Ga-rich) region, which constitutes a p-type region. The Ga-rich region then grades back to an Al-rich region, which constitutes an n-type region. This alternating pattern is continued for a desired number of material layers.

Due to the formation of superjunction periods via material deposition or growth, the periodicity of the superjunction structure 100 is limited by the precision of the layers, and may be finely tuned with nanometer (nm) precision. This contrasts with superjunction structures manufactures via iterative growth and implant or trench etching and filling/regrowth, which do not enable such precision.

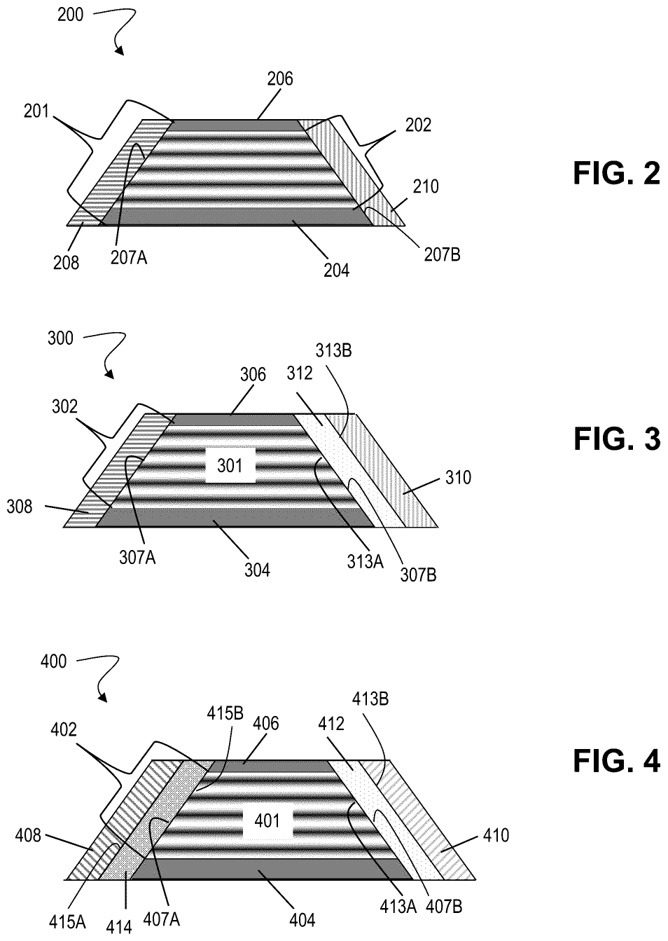

FIG. 2 is a cross-sectional side view of a superjunction (SJ) Schottky diode 200, in accordance with embodiments of the invention. The superlattice structure device 200 includes a superlattice body 201 comprised of alternating p-type and n-type graded layers (e.g., AlGaN or AlₓGa₍₁₋ₓ₎N layers) 202 grown on a metal polar substrate 204 (e.g., AlN), with a cap layer 206 (e.g., AlN) extending over the graded layers 202. A first metal sidewall layer or contact 208 extends between the substrate 204 and the cap layer 206, and is in contact with a sloping first side 207A of the superlattice body 201. A second metal sidewall layer or contact 210 extends between the substrate 204 and the cap layer 206, and is in contact with a second slopping sidewall 207B of the superlattice body 201. In implementations, the first and second metal sidewall layers 208 and 210 may comprise different metals. In embodiments, ion implantation may be performed on the superlattice body 201 with or without a subsequent annealing process to modify the superjunction doping or electric field at the trench sidewall surface (e.g., 207A and/or 207B) before the metal contact deposition or subsequent processing (e.g., semiconductor deposition or regrowth).

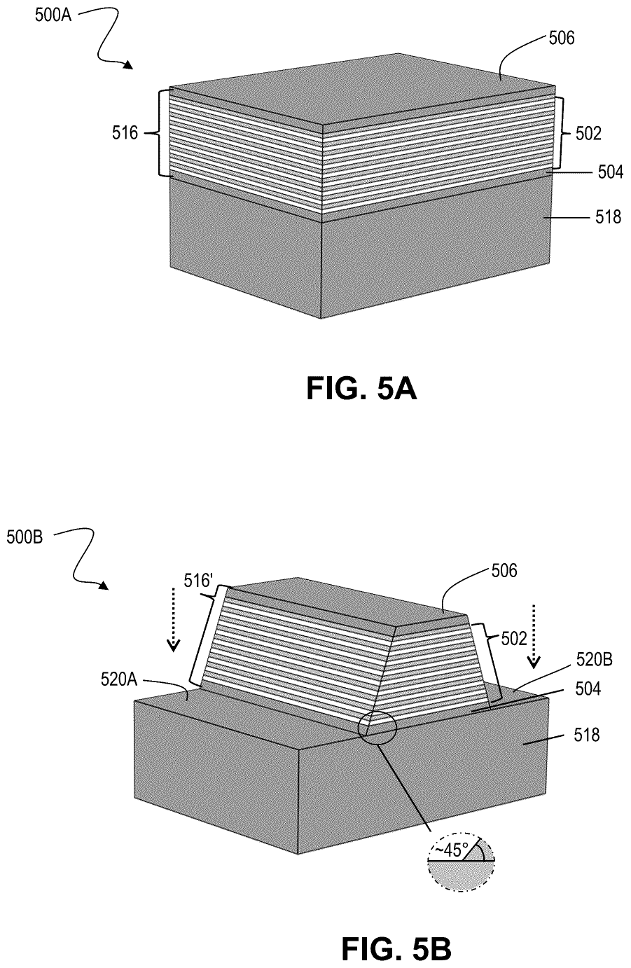

FIG. 3 is a is a cross-sectional side view of another SJ Schottky diode 300 in accordance with embodiments of the invention. The superlattice structure device 300 includes a superlattice body 301 comprised of alternating p-type and n-type graded layers (e.g., AlGaN or AlₓGa₍₁₋ₓ₎N layers) 302 grown on a metal polar substrate 304 (e.g., AlN), with cap layer 306 (e.g., AlN) extending over the graded layers 302. A first metal sidewall layer or contact 308 extends between the substrate 304 and the cap layer 306, and is in contact with a first sloping sidewall 307A of the superlattice body 301. A semiconductor sidewall layer 312 extends between the substrate 304 and the cap layer 306, and has a first side 313A in contact with a second opposing slopped sidewall 307B of the superlattice body 301. In implementations, the semiconductor sidewall layer 312 comprises n-type GaN (n-GaN). A second metal sidewall layer or contact 310 extends between the substrate 304 and the cap layer 306, and is in contact with a second side 313B of the semiconductor sidewall layer 312. In implementations, the first and second metal sidewall layers 308 and 310 may comprise different metals.

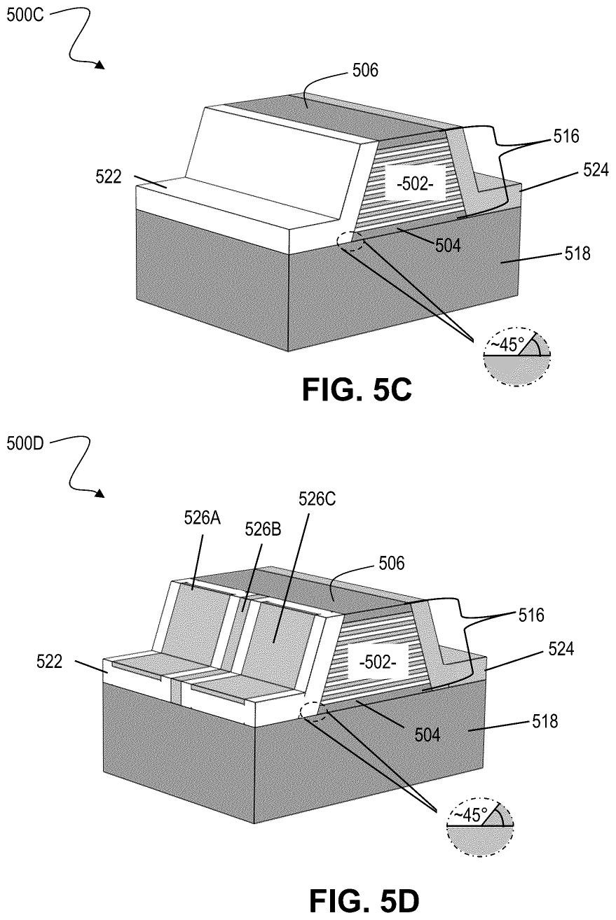

FIG. 4 is a is a cross-sectional side view of a SJ P-N diode 400 in accordance with embodiments of the invention. The superlattice structure device 400 includes a superlattice body 401 comprised of alternating p-type and n-type graded layers (e.g., AlGaN or AlₓGa₍₁₋ₓ₎N layers) 402 grown on a metal polar substrate 404 (e.g., AlN), with a cap layer 406 (e.g., AlN) extending over the graded layers 402. A first semiconductor sidewall layer 414 extends between the substrate 404 and the cap layer 406, and has an inner side 415B in contact with a first sloping sidewall 407A of the superlattice body 401. In implementations, the semiconductor sidewall layer 414 comprises p-type GaN (p-GaN). A first metal sidewall layer or contact 408 extends over an outer side 415A of the first semiconductor sidewall layer 414. A second semiconductor sidewall layer 412 extends between the substrate 404 and the cap layer 406, and has a first side 414A in contact with a second sloping sidewall 407B of the superlattice body 401. In implementations, the semiconductor sidewall layer 412 comprises nGaN. A second metal sidewall layer or contact 410 extends over an outer side 413B of the second semiconductor sidewall layer 412. In implementations, the first and second metal sidewall layers 408 and 410 may comprise different ohmic metal contacts.

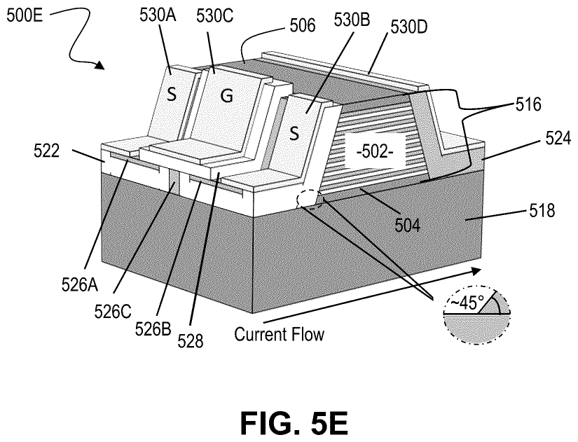

FIG. 5A is a perspective side view of a stage 500A of a superlattice structure device in accordance with embodiments of the invention. Stage 500A of the superlattice structure device includes alternating p-type and n-type graded layers (e.g., AlGaN or AlₓGa₍₁₋ₓ₎N layers) 502 grown on a metal polar substrate 504 (e.g., AlN), with a cap layer 506 (e.g., AlN) extending over the graded layers 502. Together, layers 502, 504 and 506 form a superlattice body 516. A base substrate 518 supports the superlattice body 516.

FIG. 5B is a perspective side view of a stage 500B of a superlattice structure device in accordance with embodiments of the invention. In accordance with implementations of the invention, opposing first and second angled side portions are removed from the superlattice body 516 via ion etching, ion milling, or any suitable method, thereby exposing top portions 520A, 520B of the base substrate 518. This results in a superlattice body 516′ having opposed and spaced-apart sloped sidewalls and a top surface with a width that is smaller than a width of a bottom surface.

FIG. 5C is a perspective side view of a stage 500C of a superlattice structure device in accordance with embodiments of the invention. The sidewalls of the superlattice body can be formed with a widely variable angle, from near vertical to a lower angle with respect to the base substrate 518. Generally, higher angles are preferred to obtain a less polar side-wall and to have a denser device footprint. However, higher angles can be difficult to fabricate and build on. In implementations, the sidewalls of the superlattice body 516′ are sloped at an angle of about 45 degrees (45°±5 degrees) with respect to the base substrate 518. In accordance with implementations of the invention, first and second semiconductor layers 522 and 524 are grown on respective opposing sides of the superlattice body 516′ and over respective top portions 520A and 520B of the base substrate 518. In aspects of the invention, the first semiconductor layer 522 comprises p-type GaN and the second semiconductor layer 524 comprises n-type GaN.

FIG. 5D is a perspective side view of a stage 500D of a superlattice structure device in accordance with embodiments of the invention. In accordance with implementations of the invention, an n-type dopant (e.g., silicon, oxygen) is selectively applied to portions of the first semiconductor layer 522, and is activated via annealing, thereby resulting in doped regions 526A-526C (e.g., source and Junction Field-Effect Transistor or sinker regions). In embodiments, this selective area of ion implantation and activation may be implemented utilizing Symmetric Multicycle Rapid Thermal Annealing (SMRTA), as set forth in U.S. Pat. Nos. 8,518,808; 9,543,168; and 10,854,457 or any suitable method. In implementations, doped regions are implanted antiparallel to the superjunction layers on an etched sidewall of the superjunction body to electrically contact multiple superjunction periods in one implant step.

FIG. 5E is a perspective side view of a stage 500E of a superlattice structure device (i.e., a MOSFET structure) in accordance with embodiments of the invention. In accordance with implementations of the invention, an oxide layer 528 is deposited over exposed portions of the doped regions 526A-526C. Metal contact 530A is deposited over an exposed portion of the first semiconductor layer 522 and an exposed portion of the doped region 526A, a second metal contact 530B is deposited over another exposed portion of the first semiconductor layer 522 and an exposed portion of the doped region 526B, a third metal contact 530C is deposited on the oxide layer 528, and a fourth metal contact 530D is deposited over the second semiconductor layer 524. Metal contacts 530A-530D may be deposited using an existing metallization process.

It should be understood that FIGS. 5A-5E depict exemplary manufacturing stages of a superlattice structure device, and additional stages not depicted may be utilized in its manufacture. Additionally, proportions in the drawings are shown for illustrative purposes only, and are not intended to limit embodiments of the invention. It should also be understood that different geometries than those depicted in the above-identified superlattice bodies may be utilized.

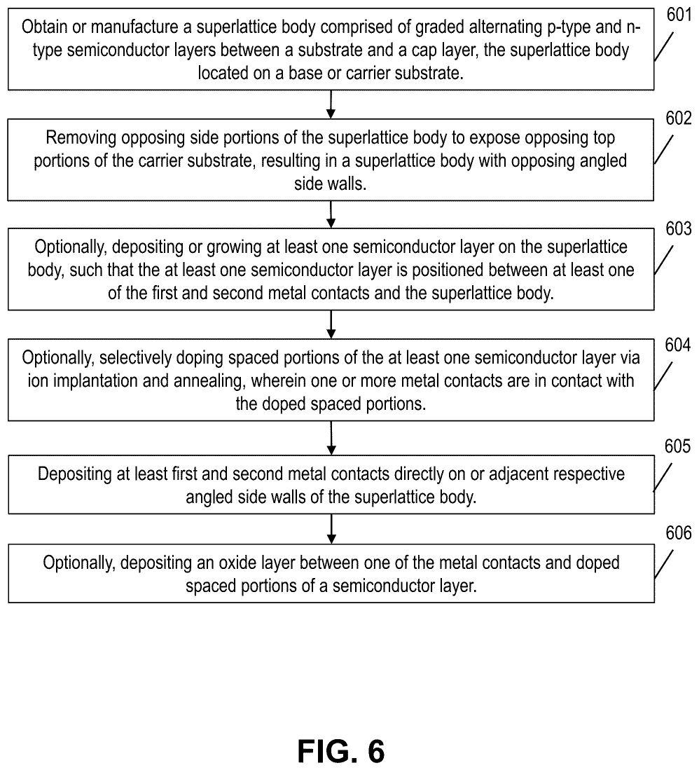

FIG. 6 shows a flowchart of an exemplary method in accordance with aspects of the present invention. Structures depicted in FIGS. 2-4 and 5E may be manufactured utilizing the method of FIG. 6.

At 601, a superlattice body on a base or carrier substrate is obtained or manufactured, where the superlattice body is comprised of compositionally graded alternating p-type and n-type semiconductor layers between a substrate and a cap layer, in-plane with the substrate. In implementations, the graded p-type and n-type semiconductor layers are selected from the group consisting of: III-V compounds, III-nitride compounds, Sc—N, Y—N, and X—N(where X is lanthanum or a lanthanoid element) and alloys thereof, III-VI compounds, III-oxide compounds, zinc oxide (ZnO), and alloys thereof. In embodiments, the substrate is a suitable material for the semiconductor layers and may comprise a metal polar or nitrogen polar substrate of AlN or GaN in the case of semiconductor layers of AlGaN alloys.

In aspects of the invention, the cap layer is a suitable material to passivate or terminate the high electric fields at the surface and may comprise AlN or insulating semiconductors or oxides of III-V compounds, III-nitride compounds, Sc—N, Y—N, and X—N(where X is lanthanum or a lanthanoid element) and alloys thereof, III-VI compounds, III-oxide compounds, ZnO, and alloys thereof. See, for example, the superlattice body 516 on the carrier substrate 518 depicted in FIG. 5A. The superlattice body may be grown during monolithic growth of the semiconductor material. In some embodiments, the superlattice body is formed through the incorporation of extrinsic dopants. In other implementations, the superlattice body is formed utilizing abrupt composition changes and polarization doping to generate the n-type and p-type layers as two-dimensional (2D) sheet charges. In other implementations, more gradual composition changes and polarization doping is used to generate n-type and p-type layers as three-dimensional (3D) doped volumes. In embodiments, a pitch of the superlattice body is less than 5 microns (μm), and preferably less than 1 μm. The term pitch as used herein refers to a distance between an edge of an n-type region and an opposing edge of a subsequent n-type region in the growth direction. The term pitch may otherwise be described as the distance over which the material composition repeats.

At 602, opposing side portions of the superlattice body are removed to expose opposing top portions of the carrier substrate, resulting in a superlattice body with opposing spaced sloped sidewalls, which are each at an oblique angle with respect to a top of the substrate. See, for example, the superlattice body 516′ of FIG. 5B. Removal methods may include ion etching and ion milling, for example. In implementations, the angle of each of the sidewalls with respect to the top of the substrate is between 1 and 90 degrees. In embodiments, trenches are cut in the superlattice body to expose top surface portions of a supporting substrate (e.g., 518 of FIGS. 5A-5E).

At 603, optionally, at least one material (semiconductor) layer is grown or deposited on a sidewall of the superlattice body before metallization, such that the material layer is positioned between at least one metal contact and the superlattice body. In the example of FIG. 3, a semiconductor layer 312 (e.g., n-type GaN) is deposited before a Schottky metal contact 310 is deposited thereon, resulting in reduced interface trap states. See also the example in FIG. 4, depicting a first semiconductor layer 414 grown or deposited on the sloped sidewall 407A of the superlattice body 401, and a second semiconductor layer 412 grown or deposited on the sloped sidewall 407B of the superlattice body 401, wherein the first and second metal contacts 408 and 410 are deposited on the respective semiconductor layers 414 and 412.

At 604, optionally, spaced portions of the at least one semiconductor layer of step 603 are doped via ion implantation and annealing, wherein one or more metal contacts are in contact with the doped spaced portion. See for example FIG. 5D, depicting doped portions 526A-526B and 526C implanted in the semiconductor layer 522. In embodiments, dopants are selected from a compatible group of dopants for the semiconductor that makes up layer 522. In the case of III-N materials for example, this group may consist of: silicon (Si), germanium (Ge), tin (Sn), oxygen (O), sulfur(S), selenium (Se), and tellurium (Te) for n-type dopants, and magnesium (Mg), beryllium (Bc), calcium (Ca), strontium (Sr), barium (Ba), zinc (Zn), and cadmium (Cd) for p-type dopants. In the case of III-Oxide materials for example, this group may consist of: silicon (Si), germanium (Ge), tin (Sn), fluorine (F), chlorine (Cl), bromine (Br), and iodine (I) for n-type dopants, and magnesium (Mg), beryllium (Be), calcium (Ca), strontium (Sr), barium (Ba), zinc (Zn), cadmium (Cd), nitrogen (N), phosphorous (P), arsenic (As), and antimony (Sb) for p-type dopants.

At 605, at least two metal contacts (i.e., first and second metal contacts) are deposited directly on or adjacent to the sloped sidewalls of the superlattice body. In one example depicted in FIG. 2, metal contacts 208 and 210 are deposited directly on opposing sloped sidewalls of the superlattice body 201, thereby forming a SJ Schottky barrier diode. In another example, depicted in FIG. 3, a first metal contact 308 is in direct contact with a first sloped sidewall 307A of the superlattice body 301, while a second metal contact 310 is deposited adjacent the second sloped sidewall 307B on a semiconductor layer 312. The metal contacts may be deposited utilizing existing metallization processes.

At 606, optionally, an oxide layer is deposited between one of the metal contacts and doped spaced portions of a semiconductor layer. See for example FIG. 5E, depicting an oxide layer 528 between a metal contact 530C and doped portions 526A-526C of the semiconductor layer 522. In implementation, the final devices resulting from the process of FIG. 6 is selected from: a superjunction Schottky barrier diode; a superjunction P-N diode; a standard superjunction MOSFET; and a superjunction MOSFET utilizing a HEMT surface device for source/junction field-effect transistor (JFET) regions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of making a superjunction semiconductor device comprising:
growing, on a substrate, alternating n-type and p-type semiconductor layers in the plane of the substrate, thereby forming a superjunction region providing a depletion effect;
etching opposing sides of the superjunction region and the substrate to form spaced first and second sloped sidewalls, wherein each of the first and second sloped sidewalls extend at an oblique angle with respect to a top surface of the substrate;
forming a first metal contact in communication with the first sidewall; and
forming a second metal contact in communication with the second sidewall.

2. The method of claim 1, wherein the superjunction region is comprised of material selected from the group consisting of: aluminum nitrides, gallium nitrides, scandium nitrides, and alloys thereof.

3. The method of claim 1, further comprising forming an epitaxial cap layer of semiconductor material over a top surface of the superjunction region between the first and second sloped sidewalls.

4. The method of claim 1, wherein each of the n-type layers and p-type layers have a graded composition.

5. The method of claim 1, further comprising utilizing polarization doping to generate the superjunction region.

6. The method of claim 1, further comprising:
depositing a first material layer on the first sloped sidewall such that the first material layer extends across the alternating n-type and p-type semiconductor layers, wherein the first metal contact is formed on the first material layer.

7. The method of claim 6, further comprising doping the first material layer via ion implantation.

8. The method of claim 6, wherein the first material layer is an n-type semiconductor.

9. The method of claim 8, wherein the first material layer is selected from the group consisting of: aluminum nitrides, gallium nitrides, scandium nitrides, and alloys thereof.

10. The method of claim 6, further comprising:
depositing a second material layer onto the second sloped sidewall such that the second material layer extends across the alternating n-type and p-type semiconductor layers, wherein the second metal contact is formed on the second material layer.

11. The method of claim 10, wherein the second material layer is a p-type semiconductor material.

12. The method of claim 11, wherein the second material layer is selected from the group consisting of: aluminum nitrides, gallium nitrides, scandium nitrides, and alloys thereof.

13. A superjunction superlattice semiconductor device comprising:
a substrate with a superlattice body grown thereon, wherein the superlattice body includes alternating n-type and p-type semiconductor layers grown in plane with the substrate to form a superjunction region providing a depletion effect, wherein the superlattice body includes first and second sloped sidewalls extending at an oblique angle to a top surface of the substrate;
a semiconductor cap layer extending over on a top surface of the superlattice body;
a first metal contact in communication with the first sidewall and the semiconductor cap layer; and
a second metal contact in communication with the second sidewall and the semiconductor cap layer.

14. The superjunction semiconductor device of claim 13, further comprising a first material layer between the first sloped sidewall and the first metal contact.

15. The superjunction semiconductor device of claim 14, further comprising a supporting substrate, wherein the first material layer is deposited on a portion of the supporting substrate.

16. The superjunction semiconductor device of claim 15, further comprising a second material layer between the second sloped sidewall and the second metal contact.

17. The superjunction semiconductor device of claim 16, wherein the second material layer is deposited on a portion of a supporting substrate.

18. The superjunction superlattice semiconductor device of claim 13, wherein the superjunction region is comprised of material selected from the group consisting of: aluminum nitrides, gallium nitrides, scandium nitrides, and alloys thereof.

19. The superjunction semiconductor device of claim 13, further comprising third and fourth metal contacts in communication with the first sloped sidewall.

20. The superjunction semiconductor device of claim 19, further comprising:
a supporting substrate;
a first material layer located between the first metal and fourth metal contacts and the superlattice body, and between the first and fourth metal contacts and the supporting substrate;
an oxide layer formed over a surface portion of the first material layer between the third metal contact and the first material layer; and
a second material layer located between the second metal contact and the superlattice body, and between the second metal contact and the supporting substrate.
